(19) United States
(12) Patent Application Publication
(10) Pub. No.: US 2024/0387239 A1
(43) Pub. Date: Nov. 21, 2024

(54) MANUFACTURING METHOD OF SEMICONDUCTOR STRUCTURE

(71) Applicant: UNITED MICROELECTRONICS CORP., Hsinchu City (TW)

(72) Inventors: Po-Tsang Chen, Tainan City (TW); Chia-Ching Lin, Kaohsiung City (TW); Wen-Liang Huang, Hsinchu City (TW)

(21) Appl. No.: 18/209,488

(22) Filed: Jun. 14, 2023

(30) Foreign Application Priority Data
May 19, 2023 (CN) 202310568214.8

(51) Int. Cl. H01L 21/762; H01L 21/8234; H01L 29/66

(52) U.S. Cl. CPC H01L 21/76229; H01L 21/823431; H01L 21/823481; H01L 29/66795

(57) ABSTRACT

A manufacturing method of a semiconductor structure includes the following steps. Fin-shaped structures are formed by patterning a first region of a semiconductor substrate. A first shallow trench is formed in a second region of the semiconductor substrate. A part of the semiconductor substrate is exposed by a bottom of the first shallow trench. A first etching process is performed. At least a part of one of the fin-shaped structures is removed by the first etching process, and the part of the semiconductor substrate exposed by the first shallow trench is partially removed by the first etching process for forming a first deep trench. The manufacturing method of the present invention may be used to achieve the purposes of process simplification and/or manufacturing cost reduction.

### BACKGROUND OF THE INVENTION

### 1. Field of the Invention

The present invention relates to a manufacturing method of a semiconductor structure, and more particularly, to a manufacturing method of a semiconductor structure including a fin-shaped structure and a deep trench.

### 2. Description of the Prior Art

As the size of the field effect transistors (FETs) becomes smaller continuously, the conventional planar field effect transistor has difficulty in development because of the manufacturing limitations. Therefore, for overcoming the manufacturing limitations, the non-planar transistor technology such as fin field effect transistor (FinFET) technology is developed to replace the planar FET and becomes a development trend in the related industries. However, in integrated circuits, the overall manufacturing process becomes complicated and the process yield and/or the manufacturing cost may be affected accordingly because different types of transistor structures, such as the above-mentioned planar and non-planar transistor structures, or different transistor structures designed for different operating voltages, have to be disposed in the integrated circuits due to product requirements.

### SUMMARY OF THE INVENTION

A manufacturing method of a semiconductor structure is provided in the present invention. A shallow trench is etched by an etching process configured to remove a fin-shaped structure for forming a deep trench, and purposes of process simplification and/or manufacturing cost reduction may be achieved accordingly.

According to an embodiment of the present invention, a manufacturing method of a semiconductor structure is provided. The manufacturing method includes the following steps. Fin-shaped structures are formed by patterning a first region of a semiconductor substrate. A first shallow trench is formed in a second region of the semiconductor substrate. A part of the semiconductor substrate is exposed by a bottom of the first shallow trench. A first etching process is performed. At least a part of one of the fin-shaped structures is removed by the first etching process, and the part of the semiconductor substrate exposed by the first shallow trench is partially removed by the first etching process for forming a first deep trench.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-8 are schematic drawings illustrating a manufacturing method of a semiconductor structure according to a first embodiment of the present invention, wherein FIG. 2 is a schematic drawing in a step subsequent to FIG. 1, FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, and FIG. 8 is a schematic drawing in a step subsequent to FIG. 7.

FIGS. 9-18 are schematic drawings illustrating a manufacturing method of a semiconductor structure according to a second embodiment of the present invention, wherein FIG. 10 is a schematic drawing in a step subsequent to FIG. 9, FIG. 11 is a schematic drawing in a step subsequent to FIG. 10, FIG. 12 is a schematic drawing in a step subsequent to FIG. 11, FIG. 13 is a schematic drawing in a step subsequent to FIG. 12, FIG. 14 is a schematic drawing in a step subsequent to FIG. 13, FIG. 15 is a schematic drawing in a step subsequent to FIG. 14, FIG. 16 is a schematic drawing in a step subsequent to FIG. 15, FIG. 17 is a schematic drawing in a step subsequent to FIG. 16, and FIG. 18 is a schematic drawing in a step subsequent to FIG. 17.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “etch” is used herein to describe the process of patterning a material layer so that at least a portion of the material layer after etching is retained. When “etching” a material layer, at least a portion of the material layer is retained after the end of the treatment. In contrast, when the material layer is “removed”, substantially all the material layer is removed in the process. However, in some embodiments, “removal” is considered to be a broad term and may include etching.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

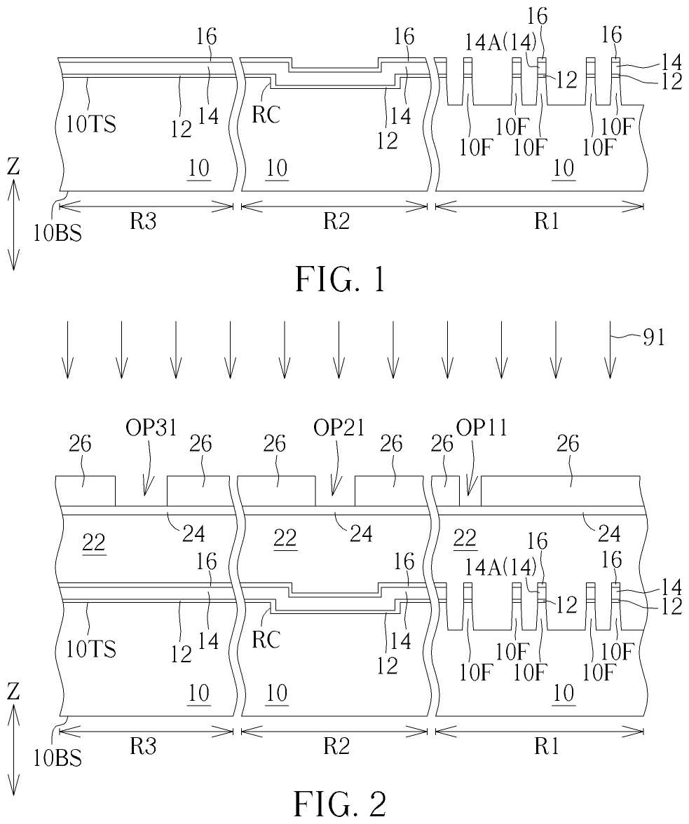

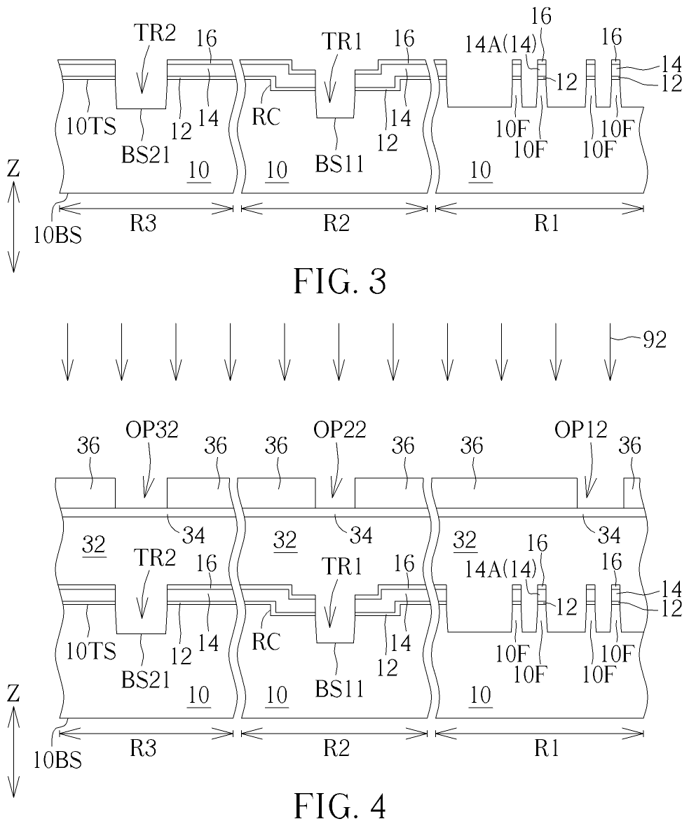

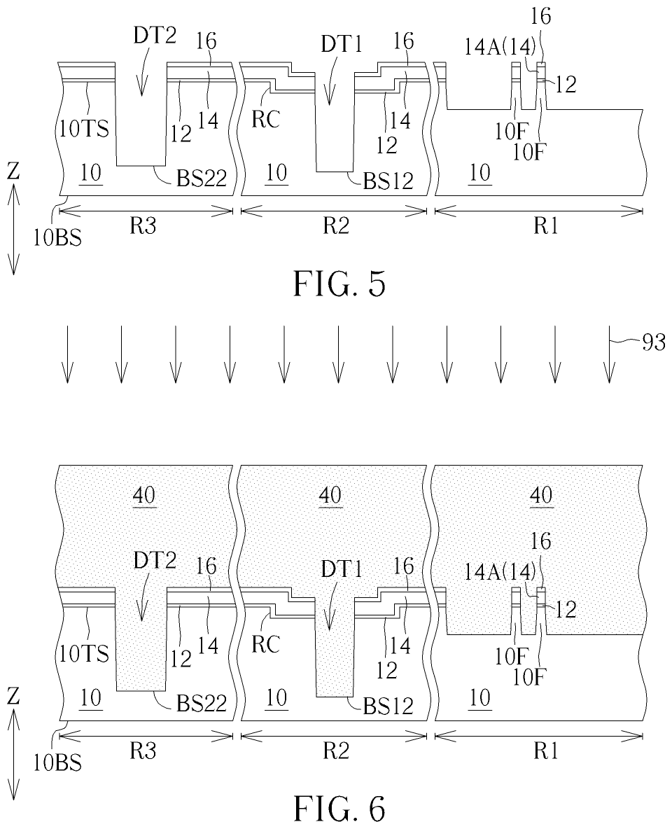

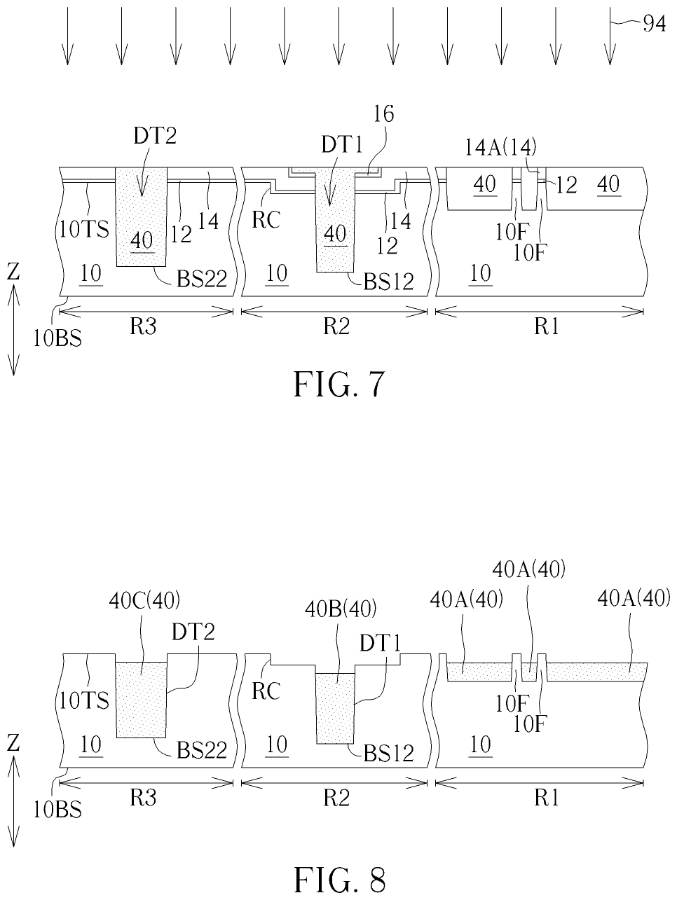

Please refer to FIGS. 1-8. FIGS. 1-8 are schematic drawings illustrating a manufacturing method of a semiconductor structure according to a first embodiment of the present invention, wherein FIG. 2 is a schematic drawing in a step subsequent to FIG. 1, FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, and FIG. 8 is a schematic drawing in a step subsequent to FIG. 7. The manufacturing method of the semiconductor structure in this embodiment may include the following steps. As shown in FIG. 1, a semiconductor substrate 10 is provided, and the semiconductor substrate 10 may include a first region R1 and a second region R2. Fin-shaped structures 10F are formed by patterning the first region R1 of the semiconductor substrate 10. Subsequently, as shown in FIG. 2 and FIG. 3, a first shallow trench TR1 is formed in the second region R2 of the semiconductor substrate 10, and a part of the semiconductor substrate 10 is exposed by a bottom BS11 of the first shallow trench TR1. As shown in FIG. 4 and FIG. 5, a first etching process (such as an etching process 92) is then performed. At least a part of one of the fin-shaped structures 10F is removed by the etching process 92, and the part of the semiconductor substrate 10 exposed by the first shallow trench TR1 is partially removed by the etching process 92 for forming a first deep trench DT1. In the manufacturing method of the present invention, the etching process configured to remove the fin-shaped structure 10F may be used to etch the shallow trench together for forming the deep trench, and the effects of process simplification and/or manufacturing cost reduction may be achieved accordingly.

Specifically, the manufacturing method in this embodiment may include but is not limited to the following steps. As shown in FIG. 1, in some embodiments, the semiconductor substrate 10 may further include a third region R3, and one or a plurality of material layers (such as a dielectric layer 12, a mask layer 14, and a dielectric layer 16) may be formed on the first region R1, the second region R2, and the third region R3 of the semiconductor substrate 10. The material layers located above the first region R1 may be patterned, and the patterned material layers (such as mask patterns 14A) may be used as mask in a patterning process performed to the first region R1 and configured to form the fin-shaped structures 10F. In some embodiments, in the step of forming the fin-shaped structures 10F, the material layers located above the second region R2 and the third region R3 may be not patterned for protecting the second region R2 and the third region R3, but not limited thereto. In some embodiments, the semiconductor substrate 10 may include a silicon substrate, a silicon germanium substrate, a silicon-on-insulator (SOI) substrate, or a substrate made of other suitable materials. In addition, the fin-shaped structure 10F may be formed by performing a patterning process to the first region R1 of the semiconductor substrate 10, and the fin-shaped structure 10F may include the semiconductor material (such as silicon, but not limited thereto) in the semiconductor substrate 10 accordingly. Additionally, the material composition of the mask layer 14 may be different from the material composition of the dielectric layer 16. For instance, the dielectric layer 12 and the dielectric layer 16 may include an oxide dielectric material (such as silicon oxide) or other suitable dielectric materials, and the mask layer 14 may include a nitride (such as silicon nitride) or other suitable mask materials.

In some embodiments, the semiconductor substrate 10 may have a top surface 10TS and a bottom surface 10BS opposite to the top surface 10TS in a vertical direction Z, the vertical direction Z may be regarded as a thickness direction of the semiconductor substrate 10, and the dielectric layer 12, the mask layer 14, and the dielectric layer 16 described above may be disposed on the side of the top surface 10TS. In addition, horizontal directions substantially orthogonal to the vertical direction Z may be substantially parallel with the top surface 10TS and/or the bottom surface 10BS of the semiconductor substrate 10, but not limited thereto. In this description, a distance between the bottom surface 10BS of the semiconductor substrate 10 and a relatively higher location and/or a relatively higher part in the vertical direction Z is greater than a distance between the bottom surface 10BS of the semiconductor substrate 10 and a relatively lower location and/or a relatively lower part in the vertical direction Z. The bottom or lower portion of each component may be closer to the bottom surface 10BS of the semiconductor substrate 10 in the vertical direction Z than the top or upper portion of this component. Another component disposed above a specific component may be regarded as being relatively far from the bottom surface 10BS of the semiconductor substrate 10 in the vertical direction Z, and another component disposed under a specific component may be regarded as being relatively closer to the bottom surface 10BS of the semiconductor substrate 10 in the vertical direction Z. Additionally, in this description, a top surface and a top portion of a specific component may include the topmost surface and the topmost portion of this component in the vertical direction Z, and a bottom surface and a bottom portion of a specific component may include the bottommost surface and a bottommost portion of this component in the vertical direction Z. Additionally, in this description, the condition that a certain component is disposed between two other components in a specific direction may include a condition that the certain component is sandwiched between the two other components in the specific direction, but not limited thereto.

In some embodiments, the fin-shaped structure 10F may protrude upwards in the vertical direction Z, and each of the fin-shaped structures 10F may be elongated in a specific horizontal direction, but not limited thereto. As show in FIG. 2 and FIG. 3, after the step of forming the fin-shaped structures 10F, a second etching process (such as an etching process 91) may be performed, at least a part of at least one of the fin-shaped structures 10F may be removed by the etching process 91, a part of the second region R2 of the semiconductor substrate 10 may be removed by the etching process 91 for forming the first shallow trench TR1, and a part of the third region R3 of the semiconductor substrate 10 may be removed by the etching process 91 for forming a second shallow trench TR2. Therefore, the second shallow trench TR2 may be formed in the third region R3 of the semiconductor substrate 10, and a part of the semiconductor substrate 10 may be exposed by a bottom BS21 of the second shallow trench TR2.

In some embodiments, a dielectric layer 22, an anti-reflection layer 24, and a photoresist layer 26 may be sequentially formed on the semiconductor substrate 10, and the etching process 91 may be performed by using the photoresist layer 26 as an etching mask, but not limited thereto. In addition, the dielectric layer 22 may include an organic distribution layer (ODL) or other suitable organic or inorganic dielectric materials, and the anti-reflection layer 24 may include silicon-containing hard mask bottom anti-reflecting coating (SHB) or other suitable anti-reflection materials. In some embodiments, the photoresist layer 26 located above the first region R1 may include an opening OP11 partially overlapping the fin-shaped structure 10F expected to be removed in the vertical direction Z, the photoresist layer 26 located above the second region R2 may include an opening OP21 overlapping the location where the first shallow trench TR1 is expected to be formed in the vertical direction Z, and the photoresist layer 26 located above the third region R3 may include an opening OP31 overlapping the location where the second shallow trench TR2 is expected to be formed in the vertical direction Z. It is worth noting that, in this description, the condition that a certain component overlaps another component in a specific direction may include a condition that the certain component overlaps another component when being viewed in the specific direction, but not limited thereto.

As shown in FIG. 2 and FIG. 3, the portion of the fin-shaped structure 10F overlaps the opening OP11 in the vertical direction Z and the dielectric layer 12, the mask pattern 14A, and the dielectric layer 16 disposed thereon may be removed by the etching process 91, and the etching process 91 may be regarded as a fin cut process or a fin remove process, but not limited thereto. The fin cut process described above may be used to remove a portion of one specific fin-shaped structure 10F for dividing the fin-shaped structure 10F and/or disconnecting the fin-shaped structure 10F, and the fin remove process described above may be used to completely remove one specific fin-shaped structure 10F, but not limited thereto. In addition, the dielectric layer 16, the mask layer 14, and the dielectric layer 12 overlapping the opening OP21 in the vertical direction Z may be removed by the etching process 91, and the etching process 91 may then etch the second region R2 downwardly for forming the first shallow trench TR1. The dielectric layer 16, the mask layer 14, and the dielectric layer 12 overlapping the opening OP31 in the vertical direction Z may be removed by the etching process 91, and the etching process 91 may then etch the third region R3 downwardly for forming the second shallow trench TR2. The dielectric layer 22, the anti-reflection layer 24, and the photoresist layer 26 may be completed removed after the etching process 91.

As shown in FIGS. 1-3, in some embodiments, before the step of forming the dielectric layer 12, a recess RC may be formed in the second region R2 of the semiconductor substrate 10. A bottom (such as a bottom surface) of the recess RC may be lower than the top surface 10TS of the semiconductor substrate 10 in the vertical direction Z. The dielectric layer 12 and/or the mask layer 14 may be partly formed in the recess RC, and the recess RC may be formed before the fin-shaped structures 10F are formed and before the first shallow trench TR1 is formed. In addition, the opening OP21 in the photoresist layer 26 and the first shallow trench TR1 may overlap the recess RC in the vertical direction Z, and the bottom BS11 of the first shallow trench TR1 may be lower than each of the fin-shaped structures 10F (such as the bottommost portion of each fin-shaped structure 10F in the vertical direction Z) and the bottom BS21 of the second shallow trench TR2 in the vertical direction Z because of the influence of the recess RC, but not limited thereto. It is worth noting that, the method of forming the first shallow trench TR1 and the second shallow trench TR2 may include but is not limited to the steps in FIG. 2 and FIG. 3 described above. Therefore, the first shallow trench TR1 and the second shallow trench TR2 may be formed by other suitable approaches according to some design considerations.

As shown in FIG. 4 and FIG. 5, after the first shallow trench TR1 and the second shallow trench TR2 are formed, the etching process 92 may be performed for removing at least at least a part of one of the fin-shaped structures 10F. In addition, the part of the semiconductor substrate 10 exposed by the first shallow trench TR1 may be partially removed by the etching process 92 for forming the first deep trench DT1, and the part of the semiconductor substrate 10 exposed by the second shallow trench TR2 may be partially removed by the etching process 92 for forming a second deep trench DT2. In other words, the first shallow trench TR1 may extend downwards to become the first deep trench DT1 by the etching process 92, and the second shallow trench TR2 may extend downwards to become the second deep trench DT2 by the etching process 92. In addition, because of the influence of the recess RC described above, a bottom BS12 of the first deep trench DT1 may be lower than a bottom BS22 of the second deep trench DT2 in the vertical direction Z, and the bottom BS22 of the second deep trench DT2 may be lower than each of the fin-shaped structures 10F (such as the bottommost portion of each fin-shaped structure 10F in the vertical direction Z) in the vertical direction Z. As shown in FIGS. 2-5, in some embodiments, the first shallow trench TR1 and the second shallow trench TR2 may be formed concurrently by the same process (such as the etching process 91), the first deep trench DT1 and the second deep trench DT2 may be formed concurrently by the same process (such as the etching process 92), the etching process 91 may be performed before the etching process 92, and the etching process 92 may be regarded as another fin cut process or another fin remove process, but not limited thereto.

As shown in FIG. 4 and FIG. 5, in some embodiments, a dielectric layer 32, an anti-reflection layer 34, and a photoresist layer 36 may be sequentially formed on the semiconductor substrate 10, and the etching process 92 may be performed by using the photoresist layer 36 as an etching mask. The dielectric layer 32, the anti-reflection layer 34, and the photoresist layer 36 may be completely removed after the etching process 92. In some embodiments, the material compositions of the dielectric layer 32 and the anti-reflection layer 34 may be identical to or similar to the material compositions of the dielectric layer 22 and the anti-reflection layer 24 in FIG. 2 described above, respectively. The photoresist layer 36 located above the first region R1 may include an opening OP12 partially overlapping the fin-shaped structure 10F expected to be removed in the vertical direction Z, the photoresist layer 36 located above the second region R2 may include an opening OP22 overlapping the first shallow trench TR1 in the vertical direction Z, and the photoresist layer 36 located above the third region R3 may include an opening OP32 overlapping the second shallow trench TR2 in the vertical direction Z. It is worth noting that, in some embodiments, the location and/or the extending direction of the opening OP12 may be different from the location and/or the extending direction of the opening OP11 in FIG. 2 described above, and the etching process 92 and the etching process 91 in FIG. 2 described above may be regarded as fin cut processes performed in different horizontal directions, but not limited thereto.

As shown in FIGS. 6-8, in some embodiments, after the first deep trench DT1 and the second deep trench DT2 are formed, a first deep trench isolation structure 40B may be formed in the first deep trench DT1, a second deep trench isolation structure 40C may be formed in the second deep trench DT2, and an isolation structure 40A may be formed between the fin-shaped structures 10F. For example, an isolation material 40 may be formed on the semiconductor substrate 10. The isolation material 40 located above the first region R1 may cover the fin-shaped structures 10F and the dielectric layer 12, the mask patterns 14A, and the dielectric layer 16 located above the fin-shaped structures 10F, and the space between the fin-shaped structures 10F may be fully filled with the isolation material 40. The first deep trench DT1 may be fully filled with the isolation material 40 located above the second region R2, and the isolation material 40 located above the second region R2 may cover the dielectric layer 12, the mask layer 14, and the dielectric layer 15 located above the second region R2. The second deep trench DT2 may be fully filled with the isolation material 40 located above the third region R3, and the isolation material 40 located above the third region R3 may cover the dielectric layer 12, the mask layer 14, and the dielectric layer 15 located above the third region R3.

Subsequently, a planarization process 93 may be performed for removing a part of the isolation material 40. In some embodiments, the planarization process 93 may include a chemical mechanical polishing (CMP) process or other suitable planarization approaches, and the planarization process 93 may stop at the mask layer 14 and the mask patterns 14A, but not limited thereto. After the planarization process 93, an etching back process 94 may be performed for removing a part of the isolation material 40 and completely removing the dielectric layer 12, the mask layer 14, and the dielectric layer 16, so as to form the isolation structure 40A, the first deep trench isolation structure 40B, and the second deep trench isolation structure 40C. In some embodiments, the isolation material 40 may be a single layer or multiple layers of insulation materials, such as an oxide insulation layer or other suitable insulation materials. The isolation structure 40A, the first deep trench isolation structure 40B, and the second deep trench isolation structure 40C may be regarded as the isolation material 40 remaining above the first region R1, the isolation material 40 remaining in the first deep trench DT1, and the isolation material 40 remaining in the second deep trench DT2 after the etching back process 94, respectively. Therefore, in some embodiments, the first deep trench isolation structure 40B, the second deep trench isolation structure 40C, and the isolation structure 40A may be formed concurrently by the same process and have the same material composition. The isolation structure 40A, the first deep trench isolation structure 40B, and the second deep trench isolation structure 40C may be formed concurrently by the same process for simplifying related process steps and avoiding negative influence generated during the processes when the isolation structure 40A and the deep trench isolation structure are formed by different processes, respectively. For example, the loading effect issue in different planarization processes performed to the first region R1 and the second region R2, respectively, may be avoided, but not limited thereto.

In some embodiments, the top surface of the isolation structure 40A may be lower than the top surface of each of the fin-shaped structures 10F in the vertical direction Z for exposing a portion of each of the fin-shaped structures 10F, the top surface of the first deep trench isolation structure 40B may be lower than the topmost portion of the first deep trench DT1 in the vertical direction Z, and the top surface of the second deep trench isolation structure 40C may be lower than the topmost portion of the second deep trench DT2 in the vertical direction Z, but not limited thereto. In some embodiments, the first region R1, the second region R2, and the third region R3 may be transistor regions for different operation voltages, such as a low voltage transistor region, a middle voltage transistor region, and a high voltage transistor region, respectively, but not limited thereto. The fin-shaped structure in the first region R1 may be a semiconductor channel region of a low voltage transistor, and the first deep trench isolation structure 40B and the second deep trench isolation structure 40C may provide isolation effect between transistor elements in the middle voltage transistor region and the high voltage transistor region, respectively. In some embodiments, required electrical performance of the transistor structure under specific operation voltage may be obtained by modify the thickness of the gate oxide layer (not illustrated) in the transistor structure, and the recess RC in the second region R2 may be used to reduce negative influence generated by increasing the thickness of the oxide layer, but not limited thereto.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

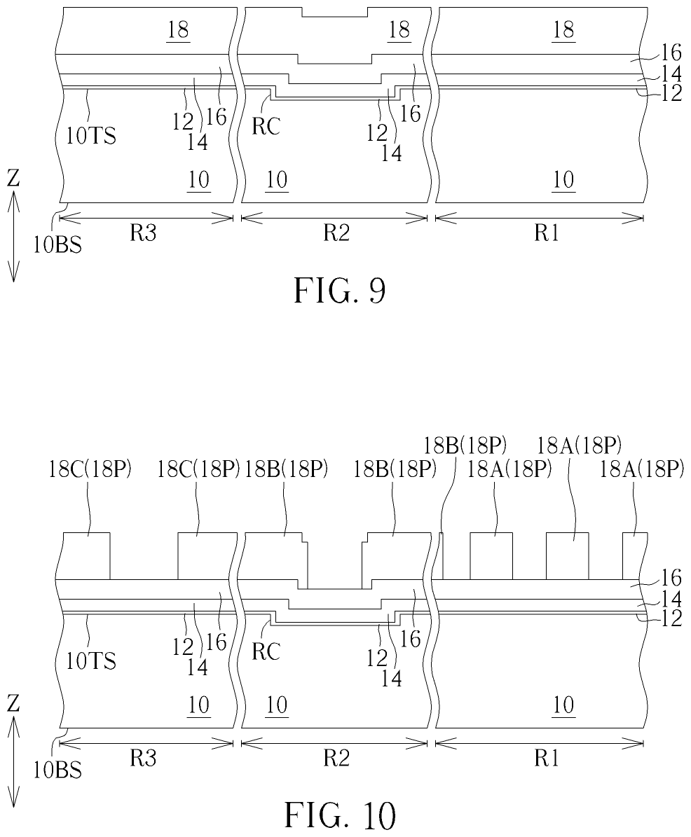

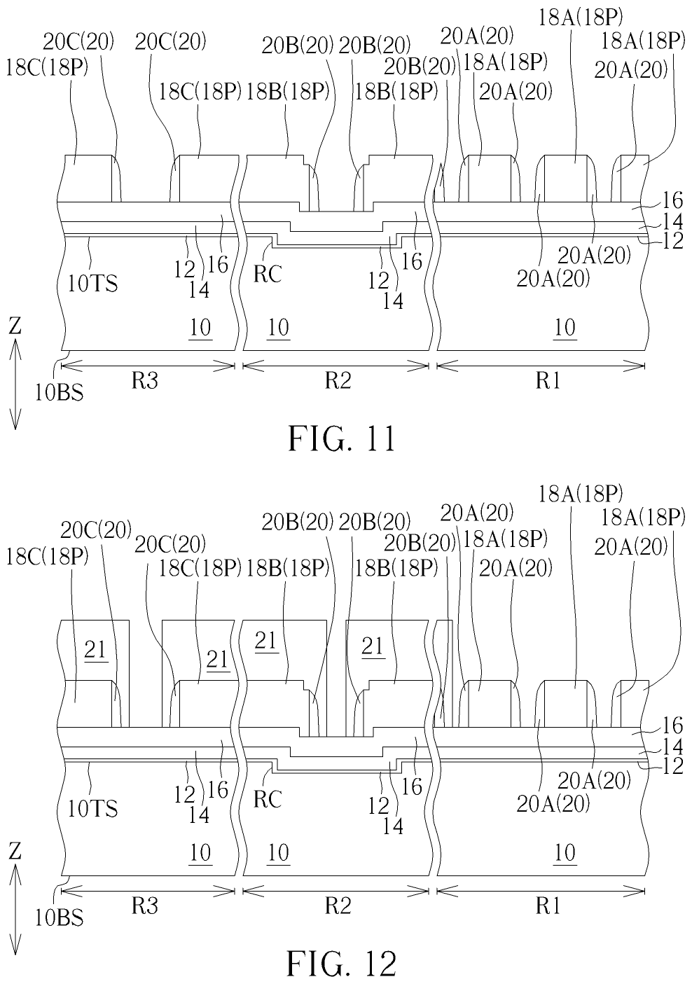

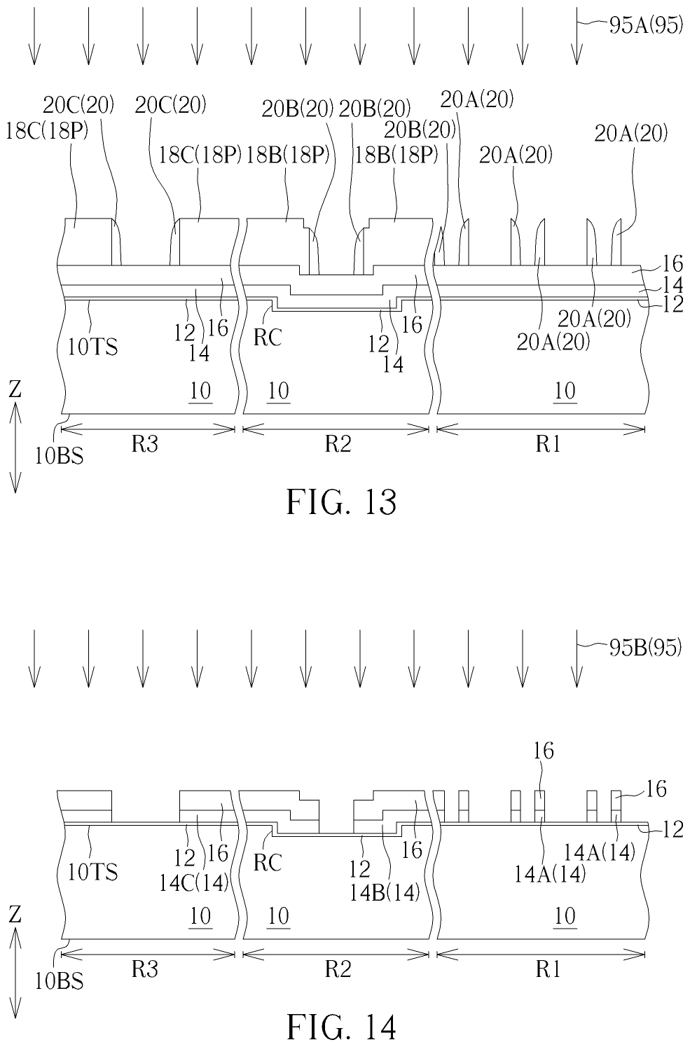

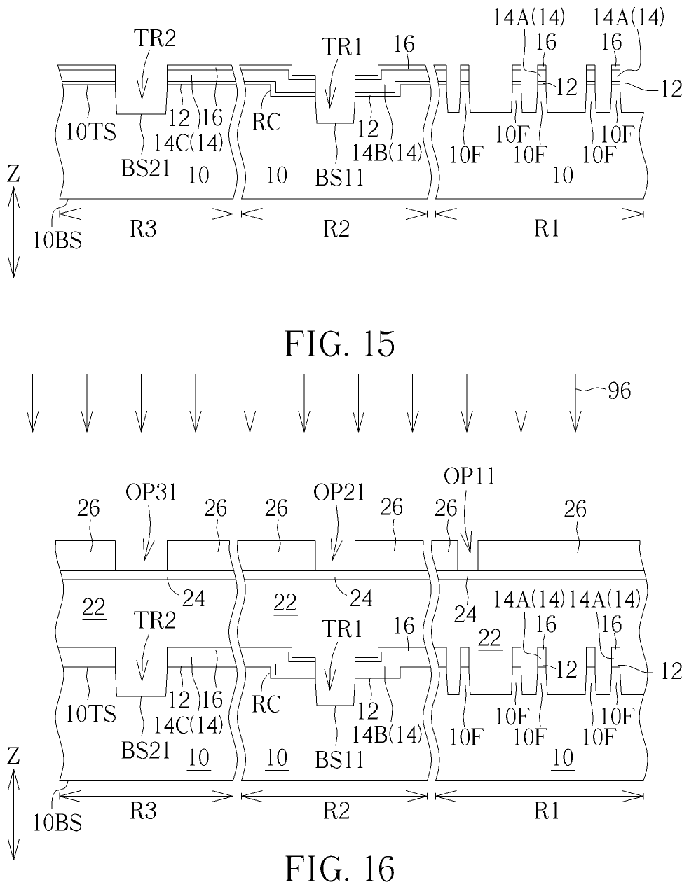

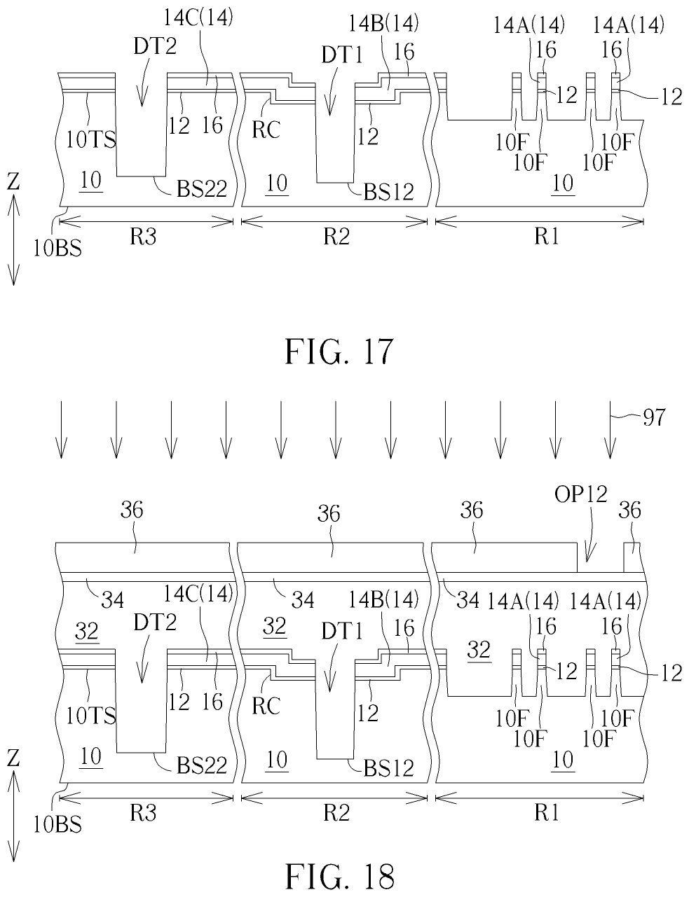

Please refer to FIGS. 9-18 and FIGS. 5-8. FIGS. 9-18 are schematic drawings illustrating a manufacturing method of a semiconductor structure according to a second embodiment of the present invention, wherein FIG. 10 is a schematic drawing in a step subsequent to FIG. 9, FIG. 11 is a schematic drawing in a step subsequent to FIG. 10, FIG. 12 is a schematic drawing in a step subsequent to FIG. 11, FIG. 13 is a schematic drawing in a step subsequent to FIG. 12, FIG. 14 is a schematic drawing in a step subsequent to FIG. 13, FIG. 15 is a schematic drawing in a step subsequent to FIG. 14, FIG. 16 is a schematic drawing in a step subsequent to FIG. 15, FIG. 17 is a schematic drawing in a step subsequent to FIG. 16, and FIG. 18 is a schematic drawing in a step subsequent to FIG. 17. In some embodiments, FIG. 5 may be regarded as a schematic drawing in a step subsequent to FIG. 18, but not limited thereto. The manufacturing method of the semiconductor substrate in this embodiment may include the following steps. As shown in FIG. 9, the semiconductor substrate 10 is provided, and the semiconductor substrate 10 may include the first region R1 and the second region R2. As shown in FIGS. 10-15, the fin-shaped structures 10F are formed by patterning the first region R1 of the semiconductor substrate 10, and the first shallow trench TR1 is formed in the second region R2 of the semiconductor substrate 10. A part of the semiconductor substrate 10 is exposed by the bottom BS11 of the first shallow trench TR1. Subsequently, as shown in FIG. 16 and FIG. 17, a first etching process (such as an etching process 96) is then performed. At least a part of one of the fin-shaped structures 10F is removed by the etching process 96, and the part of the semiconductor substrate 10 exposed by the first shallow trench TR1 is partially removed by the etching process 96 for forming the first deep trench DT1.

Specifically, the manufacturing method in this embodiment may include but is not limited to the following steps. As shown in FIG. 9, in some embodiments, after the recess RC is formed, the dielectric layer 12, the mask layer 14, the dielectric layer 16, and a mask layer 18 may be sequentially formed on the semiconductor substrate 10. In some embodiments, the mask layer 19 may include amorphous silicon, polycrystalline silicon, or other suitable materials. Subsequently, as shown in FIG. 9 and FIG. 10, the mask layer 18 may be patterned to be a patterned mask layer 18P formed above the semiconductor substrate 10. At least a part of the mask layer 18 located above the first region R1 may be patterned to be a plurality of mask patterns 18A, at least a part of the mask layer 18 located above the second region R2 may be patterned to be a mask pattern 18B, and at least a part of the mask layer 18 located above the third region R3 may be patterned to be a mask pattern 18C. In other words, the dielectric layer 12, the mask layer 14, and the dielectric layer 16 may be formed before the patterned mask layer 18P is formed, the patterned mask layer 18P may be formed above the mask layer 14, and the patterned mask layer 18P may include the mask patterns 18A disposed above the first region R1 of the semiconductor substrate 10, the mask pattern 18B disposed above the second region R2 of the semiconductor substrate 10, and the mask pattern 18C disposed above the third region R3 of the semiconductor substrate 10.

Subsequently, as shown in FIG. 11, spacers 20A may be formed on sidewalls of the mask patterns 18A, a spacer 20B may be formed on a sidewall of the mask pattern 18B, and a spacer 20C may be formed on a sidewall of the mask pattern 18C. In some embodiments, the spacers 20A, the spacer 20B, and the spacer 20C may be formed by performing an etching back process to a spacer material 20 conformally formed on the mask patterns 18A, the mask pattern 18B, the mask pattern 18C, and the dielectric layer 16. Therefore, the spacer 20A, the spacer 20B, and the spacer 20C may be formed concurrently by the same process and have the same material composition, such as including a nitride material or other materials different from that of the dielectric layer 16. Subsequently, as shown in FIG. 12 and FIG. 13, another photoresist layer 21 may be formed covering the mask pattern 18B, the spacer 20B, the mask pattern 18C, and the spacer 20C, the mask patterns 18A may be removed under this situation, and the spacers 20A may remain above the first region R1. As shown in FIG. 13 and FIG. 14, a pattern of the spacers 20A may then be transferred into the mask layer 14 for forming mask patterns 14A above the first region R1 of the semiconductor substrate 10, a pattern of the spacer 20B and the mask pattern 18B may be transferred into the mask layer 14 for forming a mask pattern 14B above the second region R2 of the semiconductor substrate 10, and a pattern of the spacer 20C and the mask pattern 18C may be transferred into the mask layer 14 for forming a mask pattern 14C above the third region R3 of the semiconductor substrate 10.

As shown in FIG. 13 and FIG. 14, in some embodiments, the mask patterns 14A, the mask pattern 14B, and the mask pattern 14C may be formed concurrently by a first etching step 95A in a patterning process 95, wherein the spacers 20A may be used as an etching mask located above the first region R1 in the first etching step 95A, the spacer 20B may be used as an etching mask located above the second region R2 in the first etching step 95A, and the spacer 20C may be used as an etching mask located above the third region R3 in the first etching step 95A. After the first etching step 95A, the spacers 20A, the spacer 20B, the spacer 20C, the mask pattern 18B, and the mask pattern 18C may be removed, and a second etching step 95B may then be performed. As shown in FIG. 14 and FIG. 15, a part of the first region R1 of the semiconductor substrate 10 may be removed by the second etching step 95B in the patterning process 95 for forming the fin-shaped structures 10F, a part of the second region R2 of the semiconductor substrate 10 may be removed by the second etching step 95B in the patterning process 95 for forming the first shallow trench TR1, and a part of the third region R3 of the semiconductor substrate 10 may be removed by the second etching step 95B in the patterning process 95 for forming the second shallow trench TR2. In some embodiments, the mask patterns 14A and the dielectric layer 16 located above the mask patterns 14A may be used as an etching mask located above the first region R1 in the second etching step 95B, the mask pattern 14B and the dielectric layer 16 located above the mask pattern 14B may be used as an etching mask located above the second region R2 in the second etching step 95B, and the mask pattern 14C and the dielectric layer 16 located above the mask pattern 14C may be used as an etching mask located above the third region R3 in the second etching step 95B.

In other words, in some embodiments, the fin-shaped structures 10F, the first shallow trench TR1, and the second shallow trench TR2 may be formed concurrently by the second etching step 95B, and the bottom BS11 of the first shallow trench TR1 may be lower than each of the fin-shaped structures 10F (such as the bottommost portion of each fin-shaped structure 10F in the vertical direction Z) and the bottom BS21 of the second shallow trench TR2 in the vertical direction Z because of the influence of the recess RC, but not limited thereto. It is worth noting that the patterning process configured to form the fin-shaped structures 10F in this embodiment may include but is not limited to the manufacturing steps illustrated in FIGS. 9-15 described above, and the fin-shaped structures 10F, the first shallow trench TR1, and the second shallow trench TR2 may be formed concurrently by other suitable approaches or may be formed separately by other suitable approaches.

As shown in FIG. 16 and FIG. 17, after the first shallow trench TR1 and the second shallow trench TR2 are formed, the etching process 96 may be performed for removing at least a part of one of the fin-shaped structures 10F. In addition, the part of the semiconductor substrate 10 exposed by the first shallow trench TR1 may be partially removed by the etching process 96 for forming the first deep trench DT1, and the part of the semiconductor substrate 10 exposed by the second shallow trench TR2 may be partially removed by the etching process 96 for forming the second deep trench DT2. In other words, the first shallow trench TR1 may extend downwards to become the first deep trench DT1 by the etching process 96, and the second shallow trench TR2 may extend downwards to become the second deep trench DT2 by the etching process 96. Therefore, the first deep trench DT1 and the second deep trench DT2 may be formed concurrently by the same process (such as the etching process 96), and the etching process 96 may be regarded as a fin cut process or a fin remove process, but not limited thereto. In addition, because of the influence of the recess RC described above, the bottom BS12 of the first deep trench DT1 may be lower than the bottom BS22 of the second deep trench DT2 in the vertical direction Z, and the bottom BS22 of the second deep trench DT2 may be lower than each of the fin-shaped structures 10F (such as the bottommost portion of each fin-shaped structure 10F in the vertical direction Z) in the vertical direction Z.

As shown in FIG. 16 and FIG. 17, in some embodiments, the dielectric layer 22, the anti-reflection layer 24, and the photoresist layer 26 may be sequentially formed on the semiconductor substrate 10, and the etching process 96 may be performed by using the photoresist layer 26 as an etching mask. The dielectric layer 22, the anti-reflection layer 24, and the photoresist layer 26 may be completely removed after the etching process 96. In some embodiments, the position of each opening in the photoresist layer 26 illustrated in FIG. 16 may be substantially identical to or close to the position of each opening in the photoresist layer 26 illustrated in FIG. 2 described above, but not limited thereto. In FIG. 16, the opening OP11 of the photoresist layer 26 may partially overlap the fin-shaped structure 10F expected to be removed in the vertical direction Z, the opening OP21 of the photoresist layer 26 may overlap the first shallow trench TR1 in the vertical direction Z, and the opening OP31 of the photoresist layer 26 may overlap the second shallow trench TR2 in the vertical direction Z, but not limited thereto.

As shown in FIGS. 16-18 and FIG. 5, a third etching process (such as an etching process 97) may be performed after the etching process 96, at least a part of one of the fin-shaped structures 10F may be removed by the etching process 97, and the etching process 97 may be regarded as another fin cut process or another fin remove process. As shown in FIG. 18 and FIG. 5, in some embodiments, the dielectric layer 32, the anti-reflection layer 34, and the photoresist layer 36 may be sequentially formed on the semiconductor substrate 10, and the etching process 97 may be performed by using the photoresist layer 36 as an etching mask. The dielectric layer 32, the anti-reflection layer 34, and the photoresist layer 36 may be completely removed after the etching process 97. In some embodiments, the opening OP12 of the photoresist layer 36 may partially overlap the fin-shaped structure 10F expected to be removed in the vertical direction Z, and there may be not any opening in the photoresist layer 36 located above the second region R2 and the third region R3 for providing a protection effect in the etching process 97, but not limited thereto. In some embodiments, the location and/or the extending direction of the opening OP12 may be different from the location and/or the extending direction of the opening OP11 in FIG. 16 described above, and the etching process 97 and the etching process 96 in FIG. 16 described above may be regarded as fin cut processes performed in different horizontal directions, but not limited thereto. Subsequently, as shown in FIGS. 5-8, the first deep trench isolation structure 40B may be formed in the first deep trench DT1, the second deep trench isolation structure 40C may be formed in the second deep trench DT2, and the isolation structure 40A may be formed between the fin-shaped structures 10F.

To summarize the above descriptions, according to the manufacturing method of the semiconductor structure in the present invention, the shallow trench may be etched by the etching process configured to remove the fin-shaped structure for forming the deep trench, and the purposes of process simplification and/or manufacturing cost reduction may be achieved accordingly. Additionally, in some embodiments, the shallow trench may be formed by the etching process configured to form the fin-shaped structures, and the related process steps may be further simplified and/or the manufacturing cost may be further reduced accordingly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A manufacturing method of a semiconductor structure, comprising:
forming fin-shaped structures by patterning a first region of a semiconductor substrate;
forming a first shallow trench in a second region of the semiconductor substrate, wherein a part of the semiconductor substrate is exposed by a bottom of the first shallow trench; and
performing a first etching process, wherein at least a part of one of the fin-shaped structures is removed by the first etching process, and the part of the semiconductor substrate exposed by the first shallow trench is partially removed by the first etching process for forming a first deep trench.

2. The manufacturing method of the semiconductor structure according to claim 1, wherein the first shallow trench extends downwards to become the first deep trench by the first etching process.

3. The manufacturing method of the semiconductor structure according to claim 1, wherein the first etching process is a fin cut process.

4. The manufacturing method of the semiconductor structure according to claim 1, wherein the bottom of the first shallow trench is lower than each of the fin-shaped structures in a vertical direction.

5. The manufacturing method of the semiconductor structure according to claim 1, wherein a method of forming the first shallow trench comprises:
performing a second etching process before the first etching process, wherein at least a part of another one of the fin-shaped structures is removed by the second etching process, and a part of the second region of the semiconductor substrate is removed by the second etching process for forming the first shallow trench.

6. The manufacturing method of a semiconductor structure according to claim 5, wherein the second etching process is a fin cut process.

7. The manufacturing method of the semiconductor structure according to claim 1, wherein the first region of the semiconductor substrate is patterned by a patterning process, and the patterning process comprises:
forming a patterned mask layer above the semiconductor substrate, wherein the patterned mask layer comprises:
first mask patterns disposed above the first region of the semiconductor substrate; and
a second mask pattern disposed above the second region of the semiconductor substrate;
forming first spacers on sidewalls of the first mask patterns and a second spacer on a sidewall of the second mask pattern; and
removing the first mask patterns.

8. The manufacturing method of the semiconductor structure according to claim 7, wherein the patterning process further comprises:
forming a mask layer on the first region and the second region of the semiconductor substrate before the patterned mask layer is formed, wherein the patterned mask layer is formed above the mask layer.

9. The manufacturing method of the semiconductor structure according to claim 8, wherein the patterning process further comprises:
transferring a pattern of the first spacers into the mask layer for forming third mask patterns above the first region of the semiconductor substrate; and
transferring a pattern of the second spacer and the second mask pattern into the mask layer for forming a fourth mask pattern above the second region of the semiconductor substrate.

10. The manufacturing method of the semiconductor structure according to claim 9, wherein the third mask patterns and the fourth mask pattern are formed concurrently by a first etching step in the patterning process.

11. The manufacturing method of the semiconductor structure according to claim 9, wherein a part of the first region of the semiconductor substrate is removed by a second etching step in the patterning process for forming the fin-shaped structures, and the third mask patterns are used as an etching mask in the second etching step.

12. The manufacturing method of the semiconductor structure according to claim 11, wherein a part of the second region of the semiconductor substrate is removed by the second etching step in the patterning process for forming the first shallow trench, and the fourth mask pattern is used as another etching mask in the second etching step.

13. The manufacturing method of the semiconductor structure according to claim 12, wherein the first shallow trench and the fin-shaped structures are formed concurrently by the second etching step.

14. The manufacturing method of the semiconductor structure according to claim 1, further comprising:
performing a third etching process after the first etching process, wherein at least a part of another one of the fin-shaped structures is removed by the third etching process.

15. The manufacturing method of the semiconductor structure according to claim 1, further comprising:
forming a second shallow trench in a third region of the semiconductor substrate, wherein a part of the semiconductor substrate is exposed by a bottom of the second shallow trench, and the part of the semiconductor substrate exposed by the second shallow trench is partially removed by the first etching process for forming a second deep trench.

16. The manufacturing method of the semiconductor structure according to claim 15, wherein the bottom of the first shallow trench is lower than the bottom of the second shallow trench in a vertical direction.

17. The manufacturing method of the semiconductor structure according to claim 15, wherein a bottom of the first deep trench is lower than a bottom of the second deep trench in a vertical direction.

18. The manufacturing method of the semiconductor structure according to claim 15, wherein the first shallow trench and the second shallow trench are formed concurrently by the same process, and the first deep trench and the second deep trench are formed concurrently by the same process.

19. The manufacturing method of the semiconductor structure according to claim 15, further comprising:
forming a first deep trench isolation structure in the first deep trench;
forming a second deep trench isolation structure in the second deep trench; and
forming an isolation structure between the fin-shaped structures, wherein the first deep trench isolation structure, the second deep trench isolation structure, and the isolation structure are formed concurrently by the same process.

20. The manufacturing method of the semiconductor structure according to claim 1, further comprising:
forming a recess in the second region of the semiconductor substrate before the first shallow trench is formed, wherein the first shallow trench overlaps the recess in a vertical direction.
